(19) United States
(12) Patent Application Publication
(10) Pub. No.: US 2003/0150634 A1
(43) Pub. Date: Aug. 14, 2003

(54) Undetachable electrical and mechnical connection, contact element for an undetachable electrical and mechanical connection, and method of producing such an electrical and mechanical connection

(76) Inventors: Gert Jakob, Stuttgart (DE); Herbert Gentner, Schwieberdingen (DE); Rainer Selig, Leonberg (DE); Erwin Liegl, Eberdingen (DE); Stefan Rysy, Ludwigsburg (DE); Juergen Enzner, Ruegland (DE); Udo Lunz, Waischenfeld (DE); Hermann Maier, Markgroeningen (DE); Ralf Haug, Leonberg (DE)

Correspondence Address: KENYON & KENYON, ONE BROADWAY, NEW YORK, NY, 10004, US

(21) Appl. No.: 10/149,168

(22) PCT Filed: Dec. 1, 2000
(86) PCT No.: PCT/DE00/04277

(30) Foreign Application Priority Data
Dec. 7, 1999 (DE) 199587760

(51) Int. Cl. H05K 5/00

(52) U.S. Cl. 174/52.1

(57) ABSTRACT

An undetachable electrical and mechanical connection (4) between a contact element (7) has contacts (31) and a counter-contact element (8) has counter-contacts (27) with a flexible section (39) of the contact element (7) in at least the area of the contacts (31). Furthermore, the contact element (7) has at least one first and second layer (21, 22) which, in the area of the flexible section (39), define a gap (23) between them in which the counter-contact element (8) is located, the first and second layer (21, 22) each having at least one contact (31) on the inside surfaces (40) of the layers facing each other and the counter-contact part (8) having at least one counter-contact on each of its top and bottom (25, 26).

The present invention relates to an undetachable electrical and mechanical connection according to the preamble of claim 1, a contact element for an undetachable electrical and mechanical connection according to the preamble of claim 18, and a method of producing such an electrical and mechanical connection according to the preamble of claim 19.

### BACKGROUND INFORMATION

For the purposes of this application, an undetachable electrical and mechanical connection is understood to be a connection in which the contact element and the counter-contact element are fixedly joined, for example, by cementing, a separation of the parts thus not being readily possible.

An undetachable electrical and mechanical connection is known, for example, from German Patent 197 19 455 C2. The electrical and mechanical connection has a contact element having contacts and a counter-contact element having counter-contacts. The contacts and counter-contacts are arranged successively in two rows. In order to produce a connection with the contact element, the latter must be attached to its counter-contact on one of the rows of counter-contacts. In order to be able to contact the other counter-contact row, a type of loop is routed from the other contact row to the counter-contact element. This loop thus spans the first contact row and is attached to the second counter-contact row. A disadvantage with this is that the two pairs of contact rows (contact row and counter-contact row) must be produced in succession. In addition, it is a disadvantage that the contact density is relatively low.

### ADVANTAGES OF THE INVENTION

In contrast, the undetachable electrical and mechanical connection having the features cited in claim 1 and the method for producing such a connection according to claim 19 offer the advantage that a cost reduction and time savings in producing the connection is possible since all contacts may be connected to the counter-contacts on the counter-contact element simultaneously. In addition, the undetachable connection is distinguished by a very flat design since it is not necessary to use a loop or span as known from the related art. Nonetheless, the undetachable electrical and mechanical connection offers high reliability with respect to mechanical strength and electrical connection, i.e., conductivity between the contacts and counter-contacts. Moreover, a savings in space is achieved, in particular if the counter-contacts are provided on one substrate since they may then be attached to the top and bottom of the substrate with the corresponding counter-contacts. With the contact element according to the present invention having the features of claim 18, it is possible to obtain the same advantages with a suitable counter-contact element.

In order to produce the mechanical connection between the contact element and the counter-contact element easily and rapidly, at least one adhesive joint is provided. For the electrical connection, an electrically conductive contacting means is arranged between the contacts and counter-contacts.

In a preferred embodiment, at least one anisotropic electrically conductive adhesive joint is produced for the electrical and mechanical connection. The adhesive joint may thus wet the entire contacting or counter-contacting area without it being necessary to ensure that the contacts and/or the counter-contacts are recessed. Anisotropic electrically conductive adhesives of this type have, for example, electrically conductive particles which are dispersed when the connection is made between each contact and the associated counter-contact and thus produce the electrical connection between one contact and counter-contact pair. The mechanical connection is thus made in a known manner by adhesion of the adhesive to the materials to be joined. Such anisotropic conductive adhesives are also identified as filled adhesives.

According to a different embodiment, the mechanical connection is produced with an unfilled adhesive and the electrical connection, i.e., the contacting means is formed by an electrically conductive film. However, the electrical connection may also be produced by direct contact between the contact and counter-contact. A contacting means may thus be omitted. As an alternative, the electrical contacting may be produced by soldering, i.e., the contacting means may have a solderable metallic alloy. The contacting means may be formed by a bow soldered connection or a laser soldered connection, which are known per se, between each contact and the respective counter-contact.

It is thus apparent that it is possible to use either a common connecting means for the electrical and mechanical connection or to provide a separate connecting means for each of the mechanical and electrical connections. In particular, the connecting means is or are applied by laminating, stencil printing, dispensing or screen printing. In this way, the connecting means may be simply applied at the locations provided for that purpose.

A particularly preferred embodiment is one in which a substrate, which includes electrical components, has the counter-contact. With the connection according to the present invention, it is thus possible to easily produce an electrical and mechanical connection from the contact element to the substrate.

In one embodiment, the contact element is connected to a sensor element so that the latter can be easily joined to the aforementioned substrate. It is thus possible to produce a compact unit from the substrate and sensor element, which has a low overall height in particular.

An embodiment is preferred in which the contact element and the sensor element are formed as one piece, the sensor element in particular being implemented as a flexible sensor pad having at least one sensor. Sensor pads of this type are used in particular in automotive engineering for passenger classification and/or for automatic child seat recognition. Sensor pads of this type are preferably designed to be pressure-sensitive. Of course, however, any other sensor element may be equipped with or have the contact element according to the present invention. Sensor elements that detect other physical variables may also be connected to the contact element of the present invention on a substrate.

By virtue of the fact that the counter-contact element is mounted between the layers of the contact element, the contacts may in particular be arranged as a contact series or contact matrix. The counter-contacts are correspondingly arranged on the counter-contact element, in particular the substrate, as a counter-contact series or counter-contact matrix.

Preferably the contacts and counter-contacts are printed conductor ends. Preferably the printed conductor end is formed to be widened in relation to the remaining printed conductor so that contact pads, which are known per se, are formed.

The printed conductors on the contact element may, for example, be formed as silver printed conductors which are preferably covered with graphite. Silver printed conductors of this type may produced in a cost-effective manner.

For a preferred embodiment, the substrate is implemented as a flexible or rigid substrate. Of course, the substrate may also be multi-layered. In particular, FR4 and LTCC are provided as circuit board materials for this purpose. Of course, any other circuit board materials may be used, in particular ceramic substrates. The surface of the substrate may, for example, be made of copper/ nickel/ gold and/or copper.

Additional exemplary embodiments are derived from the dependent claims.

### DRAWING

The present invention is described in greater detail in the following based on exemplary embodiments with reference to the drawing in which:

FIG. 1 shows a sensor element with an associated substrate, the sensor element and substrate being connected via an undetachable electrical and mechanical connection,

FIG. 2 shows a sectional view of a housing accommodating the substrate and the connection,

FIG. 3 shows an additional sectional view of the housing,

FIG. 4 shows a top view of the substrate,

FIG. 5 shows a top view of a layer of the contact element of the connection and

FIGS. 6A and 6B each show an exemplary embodiment of an electrical and mechanical connection in cross-section.

### DESCRIPTION OF THE EXEMPLARY EMBODIMENTS

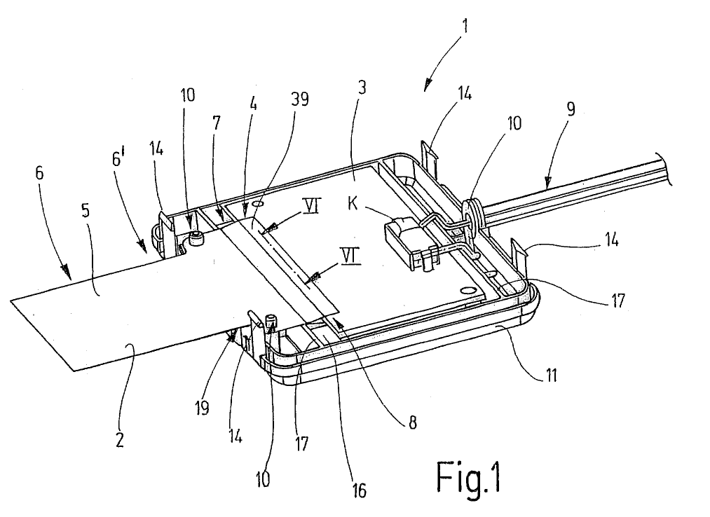

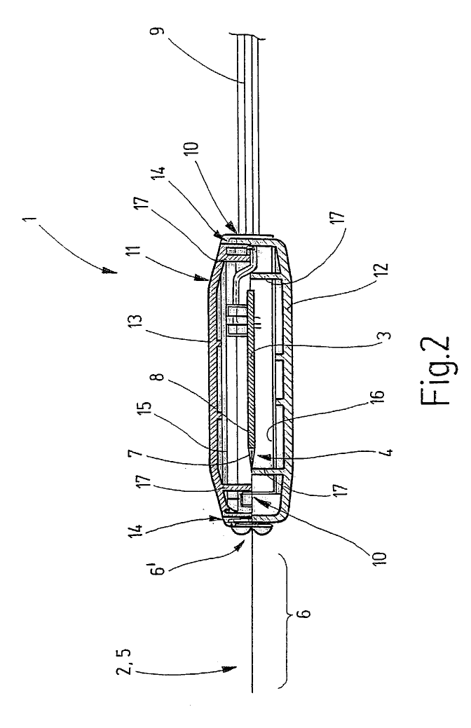

Based on FIGS. 1 to 3, the structure of a sensor device 1 will be described in greater detail in the following, the sensor device including a sensor element 2 and a substrate 3, preferably with the signal detection circuit associated with sensor element 2. Sensor element 2 and substrate 3 are connected via an electrical and mechanical connection 4.

In the exemplary embodiment, sensor element 2 is designed as a sensor pad 5 including a sensor area 6 having at least one sensor, a center portion 6′ carrying printed conductors and a contact element 7 of connection 4. Substrate 3 thus has a counter-contact element 8 of connection 4. Substrate 3 is connected to a sensor-evaluation unit, which is not shown here, via an electrical connection 9, which may be formed as a cable connection. The cable is connected to a housing 11 via a strain relief 10. The individual cables of electrical connection 9 are contacted on substrate 3 (reference symbol K).

Housing 11 has a lower housing part 12 and an upper housing part 13 which may be formed as half-shells. Preferably lower and upper housing parts 12 and 13 are fastened together by a snap connection 14 shown in FIG. 1. Housing 11 thus accommodates substrate 3 and connection 4. Sensor pad 5 thus projects out of housing 11 so that sensor area 6 is outside of housing 11. Sensor element 2 is also attached to housing 11 with a strain relief 10.

Lower housing part 12 and upper housing part 13 have a trough 15 and 16 respectively, the troughs being formed by partitions 17 and housing side walls, partitions 17 running parallel to each other at the bottom of each housing part 12 and 13. The spacing of partitions 17 of each trough 15 and 16 is dimensioned so that the substrate and connection 4 are within partitions 17. Before or after housing 11 is closed, a sealing compound 18 is introduced into both troughs 15 and 16, which fills troughs 15 and 16 and thus fixes and protects substrate 3 and connection 4.

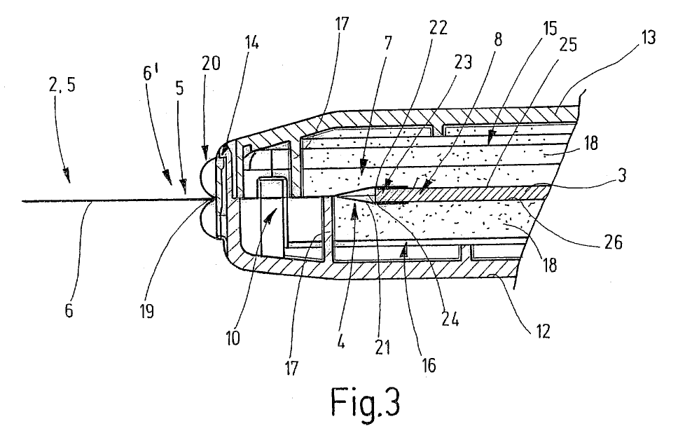

It is also apparent from FIG. 3 that the partitions of upper and lower trough 15 and 16 adjacent to a housing opening 19 are offset with respect to each other so that center portion 6′ of sensor pad 5 can be guided between these two partitions 17 to emerge through housing opening 19. In addition, at the outside of housing 19, an antikink device 20 at least partially surrounds housing opening 19, thus protecting sensor pad 5 in the area of housing opening 19.

According to FIG. 3, contact element 7 includes at least two layers 21 and 22, which enclose an intermediate space between them. If contact element 7 and sensor pad 5 are formed of one piece, these layers 21 and 22 are a component of sensor element 2 and are capable of accommodating the at least one sensor between them. An intermediate layer 24 may be situated between these two layers 21 and 22, the intermediate layer electrically insulating the printed conductors located on the insides of the layers. Intermediate layer 24 may extend as far as sensor area 6 and thus serve as a spacer. Upper layer 22 is connected to top 25 of the substrate. Lower layer 21 is correspondingly connected to bottom 26 of substrate 3. It is thus clear that counter-contact element 8 of substrate 3 comes to rest in intermediate space 23.

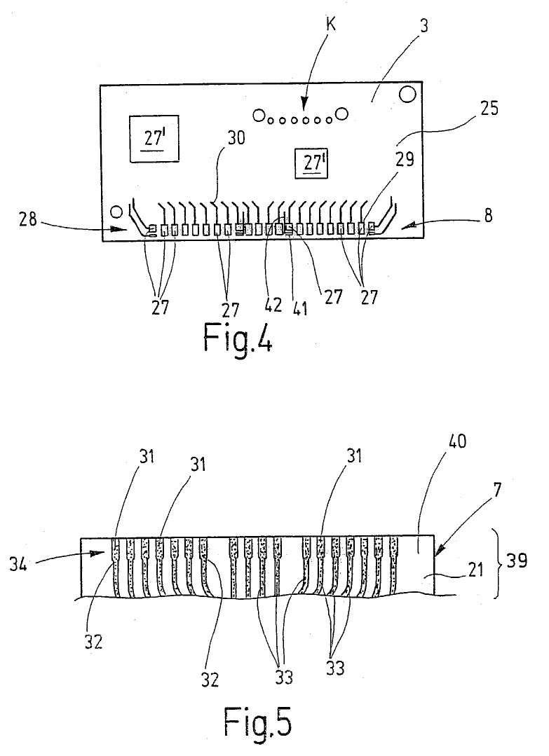

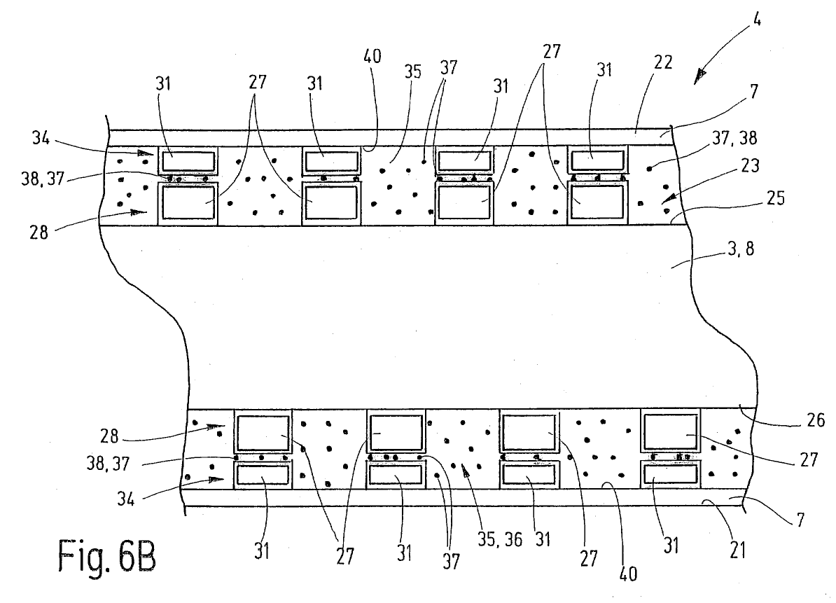

FIG. 4 shows a top view of substrate 3. It has electrical or electronic components 27′ of the signal detection circuit and —as mentioned above —counter-contact element 8, which has several counter-contacts 27, which here form a counter-contact series 28 on top 25, in which individual counter-contacts 27 have a spacing between each other. Counter-contacts 27 are located at ends 29 of printed conductors 30, which lead to electrical or electronic components 27′. Lower side 26 of substrate 3, which is not shown here, also has several counter-contacts, which also form a counter-contact series 28 (FIGS. 6A and 6B) in a preferred embodiment.

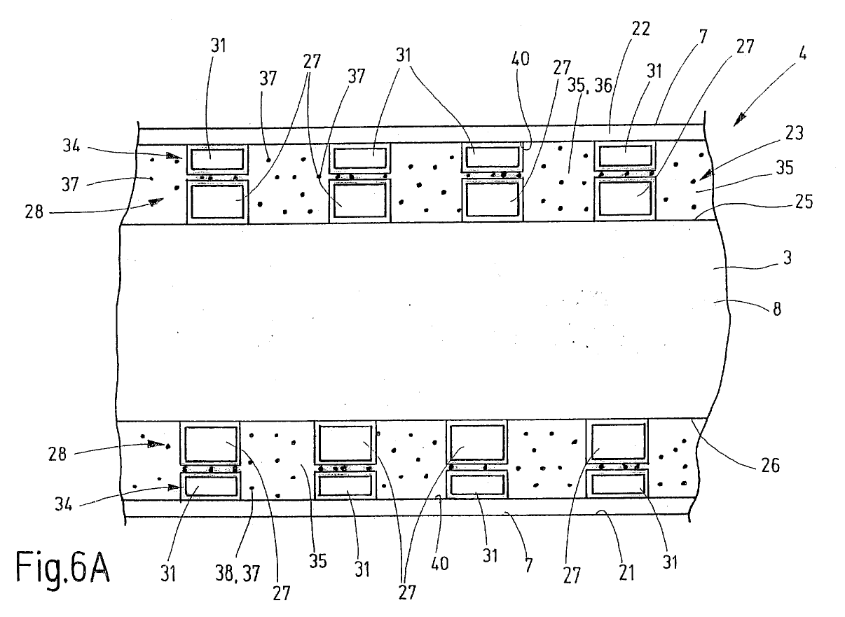

FIG. 5 shows a cutout section of contact element 7, only one layer 21 of center portion 6′ of sensor pad 5 being reproduced. Contact element 7 has several contacts 31, which are formed from ends 32 of printed conductors 33, which lead to at least one sensor. Corresponding to the arrangement of counter-contacts 27, contacts 31 are arranged in a contact series 34, the center spacing between two contacts 31 matching the center spacing between two counter-contacts 27 so that these can be placed in alignment one above the other.

FIG. 6A shows connection 4 in cross-section according to line VI-VI in FIG. 1. Identical parts or parts having the same function as in the other figures are provided with the same reference symbols. For the mechanical connection of contact element 7 to counter-contact 8, an adhesive joint 35 is provided, which in the present embodiment is also used to make the electrical connection between each contact 31 and the associated counter-contact 27, since adhesive joint 35 is implemented here by an anisotropic electrically conductive adhesive 36. The anisotropic electrical conductivity of adhesive joint 35 is produced in the exemplary embodiment by electrically conductive particles 37, between contacts 31 and counter-contacts 27. Consequently, these electrically conductive particles 37 form an electrically conductive contacting means 38, which provides the electrical connection. However, instead of the particles 37 shown here, it would also be conceivable to produce adhesive joint 35 using a non-conductive or insulating adhesive and contacting means 38 by, for example, introducing a solderable metallic alloy.

According to the exemplary embodiment of electrical and mechanical connection 4 according to FIG. 6B, contacts 31 and counter-contacts 27 of a contact series 34 or counter-contact series 28 are here arranged offset to the other contacts 31 and counter-contacts 27 of the other contact series 34 or counter-contact series 28. Compared to the embodiment according to FIG. 6A, this embodiment offers the advantage that the use of an intermediate layer 24 (FIG. 3) in the area of center portion 6′ may be omitted. Parts identical to those in the other figures are provided with the same reference symbols so that their description may thus be referred to.

Another method for the production of undetachable electrical and mechanical connection 4 between a contact element 7 having several contacts 31 and a contact element 8 having several counter-contacts 27 is described in the following: Initially, sensor pad 5 is widened in the area of flexible section 39 (FIG. 5) of center portion 6′ so that intermediate space 23 is formed for counter-contact element 8. Contacts 31 of both layers 21 and 22 are thus spaced from each other on the inside surfaces 40 of the layers (FIG. 6A). Subsequently, substrate 3 with its counter-contact element 8 is introduced into intermediate space 23. Of course, contact element 7 of sensor pad 5 may also be plugged onto substrate 3. Subsequently, contact element 7 and counter-contact element 8 are aligned in such a way that contacts 31 come to rest over matching counter-contacts 27. After that, adhesive joint 35 is produced, i.e., adhesive 36 is introduced, and the electrical contacting between contacts 31 and counter-contacts 27 is produced. For this purpose, adhesive 36 is applied in the area of counter-contact element 8 to top 25 and bottom 26 and to counter-contacts 27, preferably before contact element 7 and counter-contact element 8 are fitted together. As an alternative or in addition, adhesive 36 may also be applied to the inside surfaces 40 of the layers and/or contacts 31. Since adhesive 36 is preferably used in the form of a heat-curing adhesive, aligned connection 4 is subsequently heated and contacts 31 and counter-contacts 27 are joined, preferably under pressure, so that undetachable electrical and mechanical connection 4 is produced. This procedural step is also identified as heat sealing.

If an electrically insulating adhesive is used instead of anisotropic electrically conductive adhesive 36 is used, contacts 31 and/or counter-contacts 37 may be provided with contacting means 38, which then includes in particular a solderable metallic alloy. Heat is subsequently applied to connection 4 to cure the adhesive and to liquify the solderable metallic alloy. Heat-resistant materials are then provided for contact element 7 and counter-contact element 8.

However, contacts 31 and counter-contacts 27 may also be first joined by soldering and subsequently an adhesive may be introduced between substrate 3 and layers 21 and 22. It is thus apparent that a large number of possible variations exist with respect to the formation of electrical and mechanical connection 4.

In order to be able to assure the quality of the electrical contacting between counter-contacts 27 and contacts 31 in particular, conductivity tests are performed preferably during and/or after connection 4 has been produced. For this purpose, a test contact 41 (FIG. 4) is assigned to at least one counter-contact 27, the test contact being led out of the contacting area across a test printed conductor 42. It is thus possible to use measurements to determine the electrical connection between counter-contacts 27 and contacts 31. Of course, a test contact 41 may also be assigned to each contact 27.

In electrical and mechanical connection 4 of the present invention, it is thus critical that contacts 31 and counter-contacts 27 be arranged at two different levels (top 25 and bottom 26) which are spaced from each other. It is thus possible to increase the contact density by the bilateral, thus superimposed contacting between individual contacts 31 and respective counter-contacts 27. Connection 4 according to the present invention is also distinguished by high mechanical and electrical reliability. When undetachable electrical and mechanical connection 4 is produced, the simultaneous production of the contacting at both levels also ensures that processing times are met. In addition, connection 4 is distinguished by a flat design. Moreover, the costs for the production of connection 4 are low.

Instead of sensor pad 5, an additional contact element 7 may also be connected to center portion 6′ which carries the printed conductors. In this way, substrate 3 may be connected to another substrate or to an electrical or electronic component. It is thus possible to use a flexible printed circuit substrate, in particular center portion 6′, which has contact element 7, instead of connection 9 with its cable. Accordingly, substrate 3 does not then have contacts K but rather a counter-contact element 8.

What is claimed is:

1. An undetachable electrical and mechanical connection (4) between a contact element (7) having contacts (31) and a counter-contact element (8) having counter-contacts (27), having a flexible section (39) of the contact element (7) present at least in the area of the contacts (31), wherein the contact element (7) has at least a first and second layer (21, 22), which, in the area of the flexible section (39), have a gap (23) between them in which the counter-contact element (8) is located, the first and second layer (21, 22) each having at least one contact (31) on the inside surfaces (40) of the layers facing each other and the counter-contact element (8) having at least one counter-contact (27) each on the top and bottom (25, 26).

2. The undetachable electrical and mechanical connection according to claim 1, wherein at least one adhesive joint (35) is present for the mechanical connection between the contact element (7) and the counter-contact element (8).

3. The undetachable electrical and mechanical connection according to one of the preceding claims, wherein an electrically conductive contacting means (38) is arranged for the electrical connection between the contacts (31) and the counter-contacts (27).

4. The undetachable electrical and mechanical connection according to claim 1 or 2, wherein the contacts (31) are located directly on the counter-contacts (27).

5. The undetachable electrical and mechanical connection according to one of the preceding claims, wherein at least one anisotropic electrically conductive adhesive joint (35) is formed for the electrical and mechanical connection (4).

6. The undetachable electrical and mechanical connection according to claim 3, wherein the contacting means (38) is an anisotropic electrically conductive film or a paste.

7. The undetachable electrical and mechanical connection according to claim 1, 2 or 4, wherein the mechanical connection is formed as a non-conductive adhesive joint (35).

8. The undetachable electrical and mechanical connection according to claim 3, wherein the contacting means (38) includes a solderable metallic alloy.

9. The undetachable electrical and mechanical connection according to claim 3, wherein a bow soldering joint or laser soldering joint is formed between each of the contacts (31) and counter-contacts (27).

10. The undetachable electrical and mechanical connection according to one of the preceding claims, wherein a substrate (3) has the counter-contact element (8).

11. The undetachable electrical and mechanical connection according to one of the preceding claims, wherein the contact element (7) is connected to a sensor element (2).

12. The undetachable electrical and mechanical connection according to claim 11, wherein the contact element (7) and the sensor element (2) are formed in one piece.

13. The undetachable electrical and mechanical connection according to claim 11 or 12, wherein the sensor element (2) has a flexible sensor pad (5) having at least one sensor.

14. The undetachable electrical and mechanical connection according to one of the preceding claims, wherein the contact element (7) and the counter-contact element (8) each have several contacts or counter-contacts (31, 27), the contacts (31) being present as a contact series (34) or contact matrix or as a counter-contact series (28) or counter-contact matrix.

15. The undetachable electrical and mechanical connection according to one of the preceding claims, wherein the contacts (31) and counter-contacts (27) are printed conductor ends (29, 32).

16. The undetachable electrical and mechanical connection according to one of the preceding claims, wherein the printed conductors (33) are formed on the contact element (7) as silver printed conductors, preferably covered with graphite.

17. The undetachable electrical and mechanical connection according to one of the preceding claims, wherein the substrate (3) is implemented as a flexible or rigid substrate.

18. A contact element (7) for an undetachable electrical and mechanical connection (4) having a counter-contact element (8), the contact element (7) having several contacts (31) on a flexible section (39), in particular according to one of claims 1 to 7, wherein it has at least two layers (21, 22) which, in the area of the flexible section (39), form a gap (23) between them in which the counter-contact element (8) may be arranged, the first and second layer (21, 22) each having at least one contact (31) on the inside surfaces (40) of the layers facing each other, it being possible to connect the contacts (31) to counter-contacts (27) of the counter-contact element (8) located on the top and bottom (25, 26).

19. A method of producing an undetachable electrical and mechanical connection (4) between a contact element (7) having several contacts (31) and a counter-contact element (8) having several counter-contacts (27), in particular according to one of claims 1 to 17, wherein the end of contact element (7) provided for the connection (4) is widened, resulting in the formation of a gap (23), the contacts (31) being located on the inside surfaces (40) of the layers, the contacts (31) being aligned with the counter-contacts (27) and the contact element (7) subsequently being connected mechanically and electrically to the counter-contact element (8).

20. The method according to claim 19, wherein a test of the electrical connection between the contacts (31) and the counter-contacts (27) is performed during and/or after the production of the connection (4).
